(19) United States
(12) Patent Application Publication
(10) Pub. No.: US 2025/0201711 A1
(43) Pub. Date: Jun. 19, 2025

(54) ENLARGED PLACEHOLDER AND BACKSIDE CONTACT

(71) Applicant: INTERNATIONAL BUSINESS MACHINES CORPORATION, ARMONK, NY (US)

(72) Inventors: Lijuan Zou, Albany, NY (US); Tao Li, Slingerlands, NY (US); Ruilong Xie, Niskayuna, NY (US); Nicolas Jean Loubet, GUILDERLAND, NY (US)

(21) Appl. No.: 18/537,873

(22) Filed: Dec. 13, 2023

(51) Int. Cl. H01L 23/528; H01L 29/06; H01L 29/40; H01L 29/417; H01L 29/423; H01L 29/66; H01L 29/775

(52) U.S. Cl. CPC H01L 23/5286; H10D 30/014; H10D 30/43; H10D 30/6729; H10D 30/6735; H10D 62/121; H10D 64/01

(57) ABSTRACT

A nanosheet semiconductor structure including a backside contact structure, where the backside contact structure has a faceted profile extending beneath one or more gates, a placeholder adjacent to the backside contact structure and directly beneath a source drain region, and a dielectric liner surrounding a bottom portion of the placeholder.

### BACKGROUND

The present invention generally relates to semiconductor structures, and more particularly to nanosheet transistor structures having an enlarged placeholder and backside contact.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a backside contact structure, where the backside contact structure has a faceted profile extending beneath one or more gates, a placeholder adjacent to the backside contact structure and directly beneath a source drain region, and a dielectric liner surrounding a bottom portion of the placeholder.

According to another embodiment of the present invention, a semiconductor structure is provided. The semiconductor structure may include a backside contact structure having a faceted profile extending laterally in a direction perpendicular to one or more gates, a placeholder adjacent to the backside contact structure and directly beneath a source drain region, and a dielectric liner surrounding a bottom portion of the placeholder.

According to another embodiment of the present invention, a semiconductor structure is provided. The semiconductor structure may include a backside contact structure directly beneath and contacting a first source drain region, where the backside contact structure comprises a faceted profile, a placeholder adjacent to the backside contact structure and directly beneath a second source drain region, and a dielectric liner surrounding a bottom portion of the placeholder.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2 and 3 are cross-sectional views of the semiconductor structure during an intermediate step of a method of fabricating nanosheet transistor structures according to an exemplary embodiment;

FIGS. 4 and 5 are cross-sectional views of the semiconductor structure after flipping the assembly and recessing the substrate according to an exemplary embodiment;

FIGS. 6 and 7 are cross-sectional views of the semiconductor structure after removing and recessing remaining portions of the substrate 102 and trimming the placeholders according to an exemplary embodiment;

FIGS. 8 and 9 are cross-sectional views of the semiconductor structure after forming a liner according to an exemplary embodiment;

FIGS. 10 and 11 are cross-sectional views of the semiconductor structure after mask and removing portions of the liner according to an exemplary embodiment;

FIGS. 12 and 13 are cross-sectional views of the semiconductor structure after removing portions of the liner according to an exemplary embodiment;

FIGS. 14 and 15 are cross-sectional views of the semiconductor structure after removing the mask and enlarging the exposed placeholders according to an exemplary embodiment;

FIGS. 16 and 17 are cross-sectional views of the semiconductor structure after forming a backside dielectric layer according to an exemplary embodiment; and

FIGS. 18 and 19 are cross-sectional views of the semiconductor structure after removing the placeholders and the placeholder extensions, forming a backside contact structures, and forming backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional backside contact and placeholder fabrication techniques result in reduced backside contact size due to placeholder trimming during substrate removal.

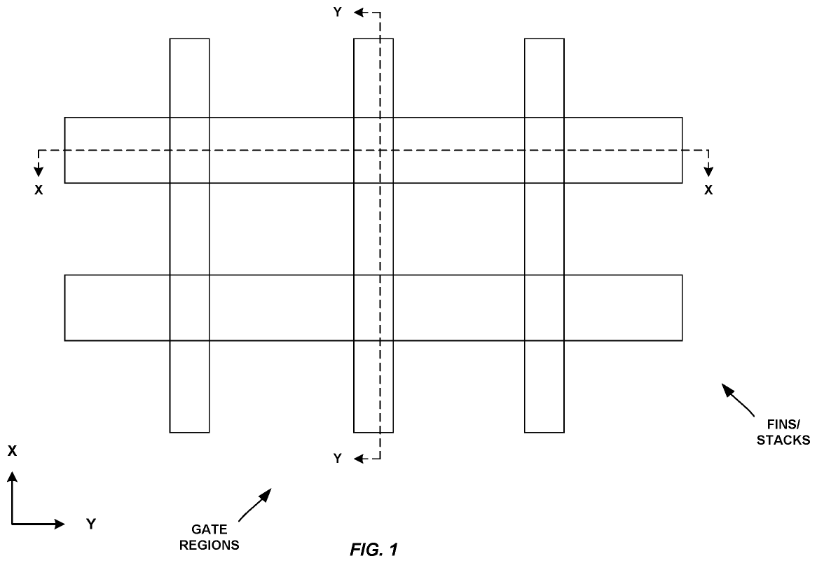

The present invention generally relates to semiconductor structures, and more particularly to nanosheet transistor structures having an enlarged placeholder and backside contact. More specifically, the nanosheet transistor structures and associated method disclosed herein enable a novel solution for providing nanosheet transistor structures having an enlarged placeholder and backside contact. Exemplary embodiments of nanosheet transistor structures having an enlarged placeholder and backside contact are described in detail below by referring to the accompanying drawings in FIGS. 1 to 21. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-21 represent cross section views oriented as indicated in FIG. 1.

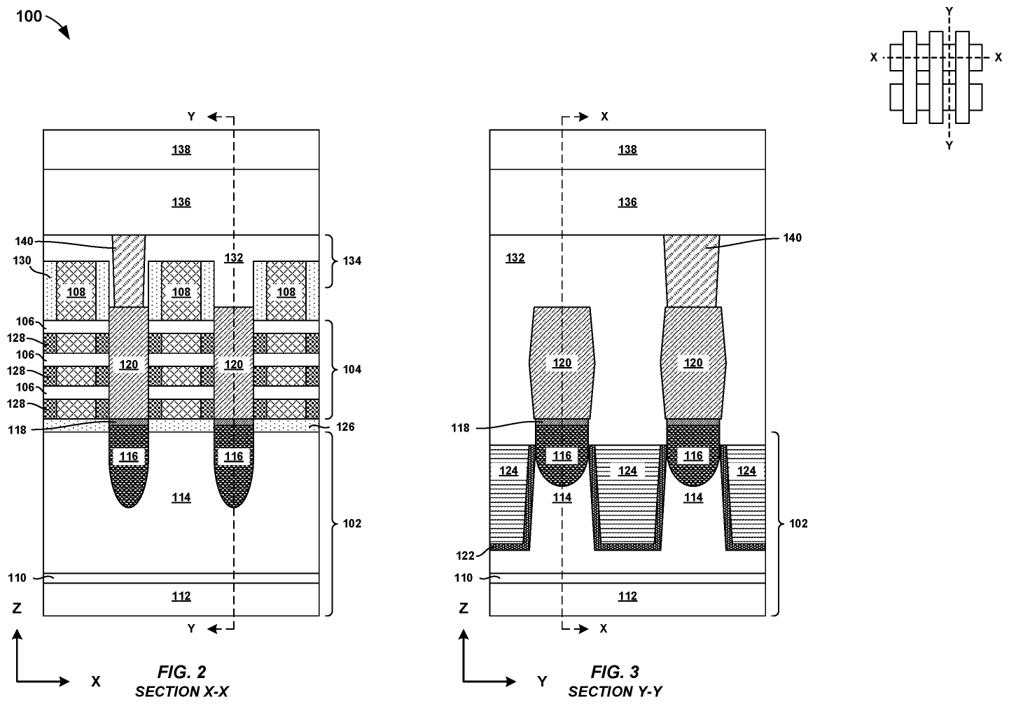

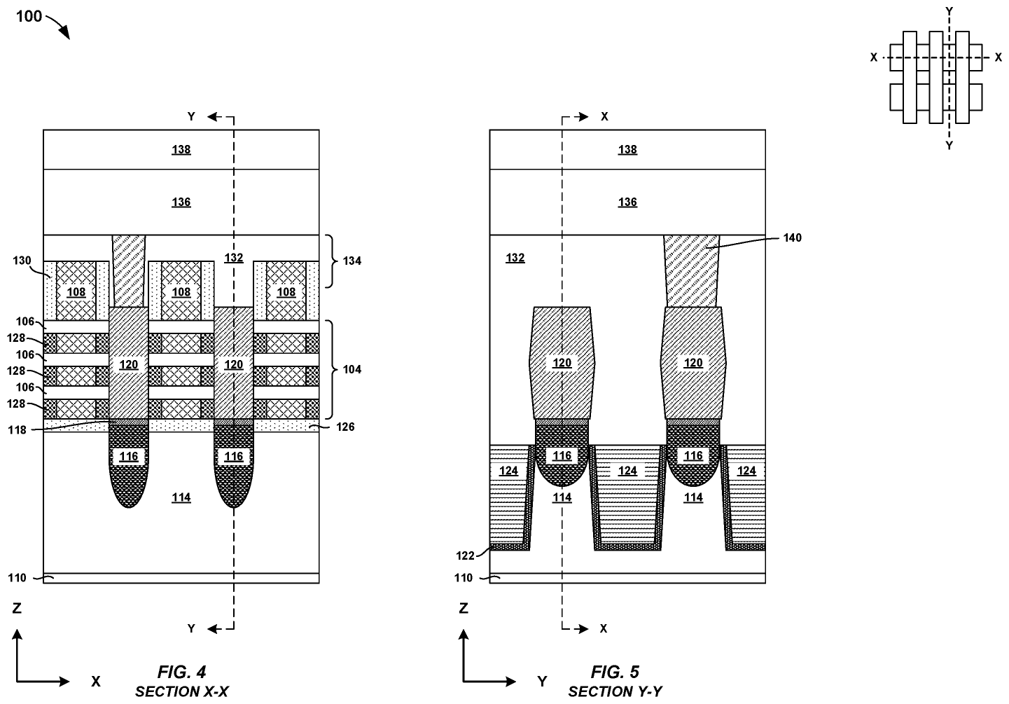

Referring now to FIGS. 2 and 3, a structure 100 is shown during an intermediate step of a method of fabricating a nanosheet transistor structure according to an embodiment of the invention. FIG. 2 depicts a cross-sectional view of the structure 100 shown in FIG. 3 taken along line X-X and FIG. 3 depicts a cross-sectional view of the structure 100 shown in FIG. 4 taken along line Y-Y.

The structure 100 illustrated in FIGS. 2-3 includes an array of nanosheet transistors formed on a substrate 102 in accordance with known techniques. As illustrated, the array of nanosheet transistors includes nanosheet stacks 104. Each nanosheet stack 104 includes a plurality of silicon channels 106 surrounded by a single gate 108. For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes placeholders 116, buffer layers 118, and source drain regions 120 generally arranged between adjacent nanosheet stacks 104, as illustrated.

The placeholders 116 are formed by filling self-aligned openings in the top semiconductor layer 114 between adjacent nanosheet stacks 104 with a sacrificial material according to known techniques. Specifically, after filling, the sacrificial material is recessed to create the placeholders 116 according to known techniques. In an embodiment, the sacrificial material is silicon germanium or amorphous silicon epitaxially grown from the surfaces of the top semiconductor layer 114. In another embodiment, the sacrificial material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the silicon channels 106.

The buffer layers 118 are formed on top of the placeholders 116 according to known techniques. Specifically, an etch stop material is formed directly on top of the placeholders 116. In an embodiment, the etch stop material can be any silicon-based material suitable to provide needed etch stop properties during backside processing. For example, the buffer layers 118 are designed to allow the subsequent removal of the placeholders 116 selective to the source drain regions 120.

The source drain regions 120 are formed on top of the buffer layer 118 according to known techniques. Specifically, the source drain regions 120 are disposed between adjacent nanosheet stacks 104 in direct contact with exposed ends of the silicon channels 106. More specifically, the source drain regions 120 may be epitaxially grown from the exposed ends of the silicon channels 106 according to known techniques.

The structure 100 further includes shallow trench isolation regions (hereinafter “STI regions”) which extend partially into the substrate 102 below the array of nanosheet transistors. In general, the STI regions may each include an isolation liner 122 and an isolation fill 124. For example, the isolation liner 122 is SiN, SiON, or SiOCN, and the isolation fill 124 is silicon oxide (SiO) or silicon nitride (SiN).

The structure 100 further includes stack spacers 126, inner spacers 128, and gate spacers 130.

The stack spacers 126 are disposed directly beneath the nanosheet stacks 104 separating them from the substrate 102. Specifically, for example, a relatively thin layer of silicon nitride is conformally deposited prior to forming the nanosheet stacks 104. In some embodiments, for example, the stack spacers 126 may be composed of SiN, SiBCN, SiOCN, SiOC, or any other combination of low-k materials. Like the buffer layers 118, the stack spacers 126 can provide etch selectivity during backside processing.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The inner spacers 128 are disposed between alternate channels (106), and laterally separate the gates 108 from the source drain regions 120, as illustrated. The inner spacers 128 provide necessary electrical insulation between the gates 108 and the source drain regions 120.

The gate spacers 130 are added to define the channel length and the source drain regions, and ultimately electrically insulate the gates 108 from subsequently formed structures, such as, for example, source drain contact structures. The gate spacers 130 are critical for electrically insulating the gates 108 from the source drain regions 120 or subsequently formed contact structures. In at least one embodiment, the gate spacers 130 include silicon nitride, silicon boron nitride, silicon carbon nitride, silicon boron carbon nitride, or other known equivalents.

Finally, the structure 100 further includes a dielectric layer 132 directly above and surrounding the source drain regions 120. The dielectric layer 132 is composed of any suitable interlayer dielectric material, such as, for example, oxides such as silicon oxide (SiOₓ), nitrides such as silicon nitride (SiₓN_{y}), and/or low-K materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 132. Using a self-planarizing dielectric material as the dielectric layer 132 can avoid the need to perform a subsequent planarizing step. After formation, top surfaces of the dielectric layer 132 are typically made flush, or substantially flush, with top surfaces of the gates 108 and the gate spacers 130 by chemical mechanical polishing techniques.

The structure 100 further includes a middle-of-line 134, a back-end-of-line 136, a carrier wafer 138.

The middle-of-line 134 includes source drain contacts 140 and gate contacts (not shown) which may be generally referred to as middle-of-line contacts. The source drain contacts 140 and the gate contacts are formed according to known techniques. The back-end-of-line 136 may include vias and metal lines which may be generally referred to as back-end-of-line interconnects. The vias and the metal lines are formed according to known techniques. Finally, the wafer 138 is secured to a top of the structure 100 according to an embodiment of the invention. The carrier wafer 138 is attached, or removably secured, to the back-end-of-line 136. In general, and not depicted, the carrier wafer 138 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 138 according to known techniques.

Although only a limited number of components, devices, or structures are shown, embodiments of the present invention shall not be limited by any quantity otherwise illustrated or discussed herein.

Referring now to FIGS. 4 and 5, the structure 100 is shown after flipping the assembly and recessing the substrate 102 according to an embodiment of the invention. FIG. 4 depicts a cross-sectional view of the structure 100 shown in FIG. 5 taken along line X-X and FIG. 5 depicts a cross-sectional view of the structure 100 shown in FIG. 4 taken along line Y-Y.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

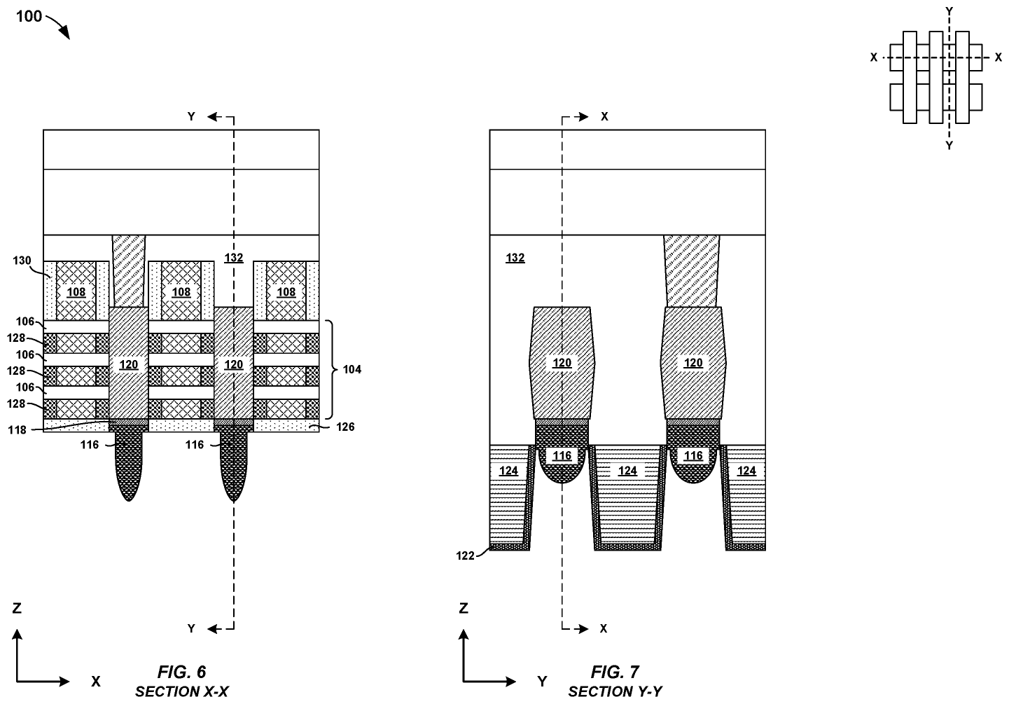

Referring now to FIGS. 6 and 7, the structure 100 is shown after removing and recessing remaining portions of the substrate 102 and trimming the placeholders 116 according to an embodiment of the invention. FIG. 6 depicts a cross-sectional view of the structure 100 shown in FIG. 7 taken along line X-X and FIG. 7 depicts a cross-sectional view of the structure 100 shown in FIG. 6 taken along line Y-Y.

First, the etch stop layer 110 is selectively removed and the top semiconductor layer 114 is recessed according to known techniques. Specifically, the etch stop layer 110 is removed selective to the top semiconductor layer 114 and the top semiconductor layer 114 is removed selective to the placeholders 116, the stack spacers 126, the gates 108, and the STI regions, as illustrated. As indicated in the figures, some erosion of the placeholders 116 is anticipated to be an unintended consequence resulting from selectively removing the top semiconductor layer 114. Such erosion would normally lead to smaller backside contacts using conventional fabrication techniques. For example, when the placeholder 116 are removed and replaced with the contact material, the resulting backside contact mimic the eroded shape and size of the placeholders 116 which causes undesirable increases in resistance.

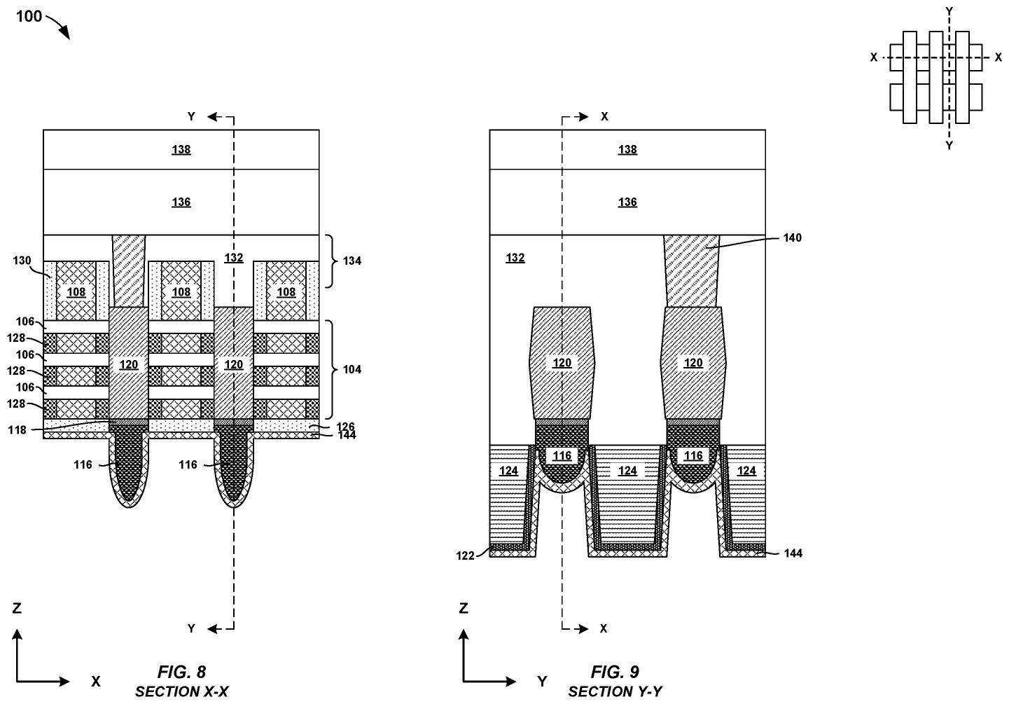

Referring now to FIGS. 8 and 9, the structure 100 is shown after forming a dielectric liner 144 according to an embodiment of the invention. FIG. 8 depicts a cross-sectional view of the structure 100 shown in FIG. 9 taken along line X-X and FIG. 9 depicts a cross-sectional view of the structure 100 shown in FIG. 8 taken along line Y-Y.

First, the dielectric liner 144 is formed across the backside of the structure 100 according to known techniques. Specifically, a liner material is conformally deposited across exposed surfaces on the backside of the structure 100 including directly on the placeholders 116 and the stack spacers 126 (see FIG. 8) and within the openings between STI regions (see FIG. 9), as illustrated. In some embodiments, for example, the dielectric liner 144 may be composed of other low-k materials, such as, for example, SiN, SiBCN, SiOCN, SiOC, or other combinations thereof. According to embodiments of the present invention, the dielectric liner 144 provide etch selectivity during backside processing. More specifically, the dielectric liner 144 must be made from a material which may be removed selective to the placeholders 116, as described below.

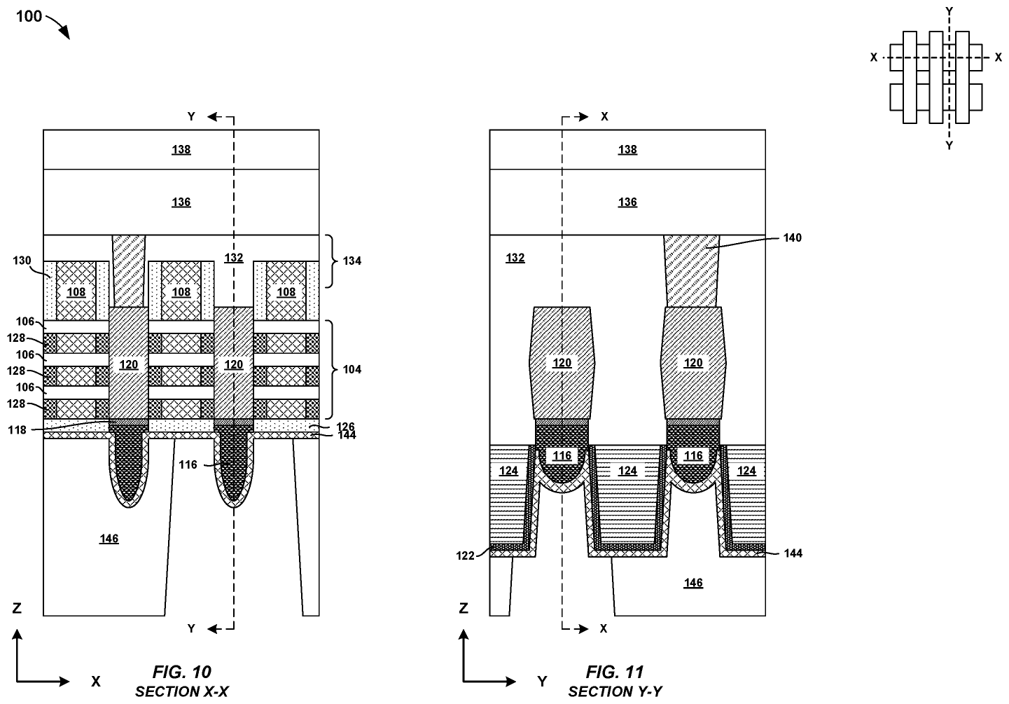

Referring now to FIGS. 10 and 11, the structure 100 is shown after forming a mask 146 and removing portions of the dielectric liner 144 according to an embodiment of the invention. FIG. 10 depicts a cross-sectional view of the structure 100 shown in FIG. 11 taken along line X-X and FIG. 11 depicts a cross-sectional view of the structure 100 shown in FIG. 10 taken along line Y-Y.

First, the mask 146 is deposited and subsequently patterned to expose certain portions of the structure 100 according to known techniques. The mask 146 can be an organic planarization layer (OPL) or a layer of material that is capable of being planarized or etched by known techniques. In an embodiment, for example, the mask 146 can be an amorphous carbon layer able to withstand subsequent processing temperatures. The mask 146 can preferably have a thickness sufficient to cover existing structures. After depositing the mask 146, a dry etching technique is applied to pattern or recess the mask 146 according to known techniques. The mask 146 is patterned consistent with a size and a location of subsequently formed backside contacts. For example, after patterning the mask 146, portions of the structure 100 in contact regions are exposed, as illustrated. Specific to the embodiments disclosed herein, the mask 146 is patterned selective to the dielectric liner 144, as illustrated.

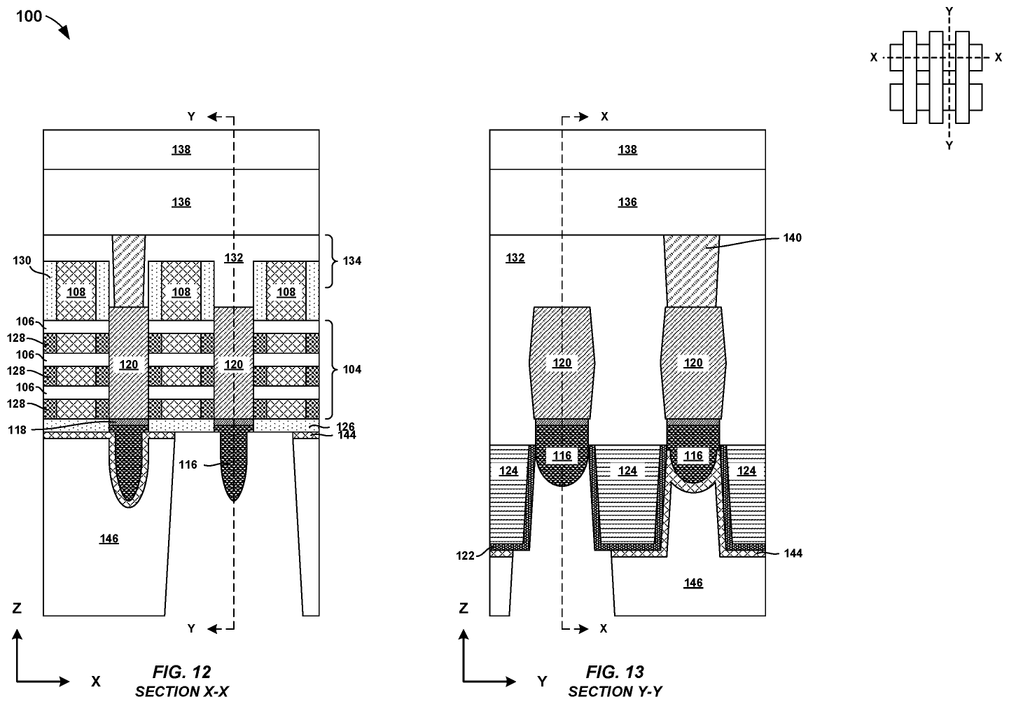

Referring now to FIGS. 12 and 13, the structure 100 is shown after removing portions of the dielectric liner 144 according to an embodiment of the invention. FIG. 12 depicts a cross-sectional view of the structure 100 shown in FIG. 13 taken along line X-X and FIG. 13 depicts a cross-sectional view of the structure 100 shown in FIG. 12 taken along line Y-Y.

Exposed portions of the dielectric liner 144 are selectively remove according to known techniques. Specifically, exposed portions of the dielectric liner 144 are removed using known etching techniques suitable to remove silicon-based materials selective to the mask 146, the placeholders 116, and the stack spacers 126. In an embodiment, the exposed portions of the dielectric liner 144 are removed using an anisotropic etch such as, for example, reactive ion etching. After removing the exposed portions of the dielectric liner 144, bottom portions of the placeholders 116 are exposed, as illustrated.

In all cases, at least portions of the dielectric liner 144 must remain in non-contact regions of the structure 100. Said differently, the dielectric liner 144 shall only be removed in contact regions of the structure 100, as illustrated. For example, the portions of the dielectric liner 144 remaining in the non-contact regions of the structure 100 will serve as a protective layer during subsequent processing.

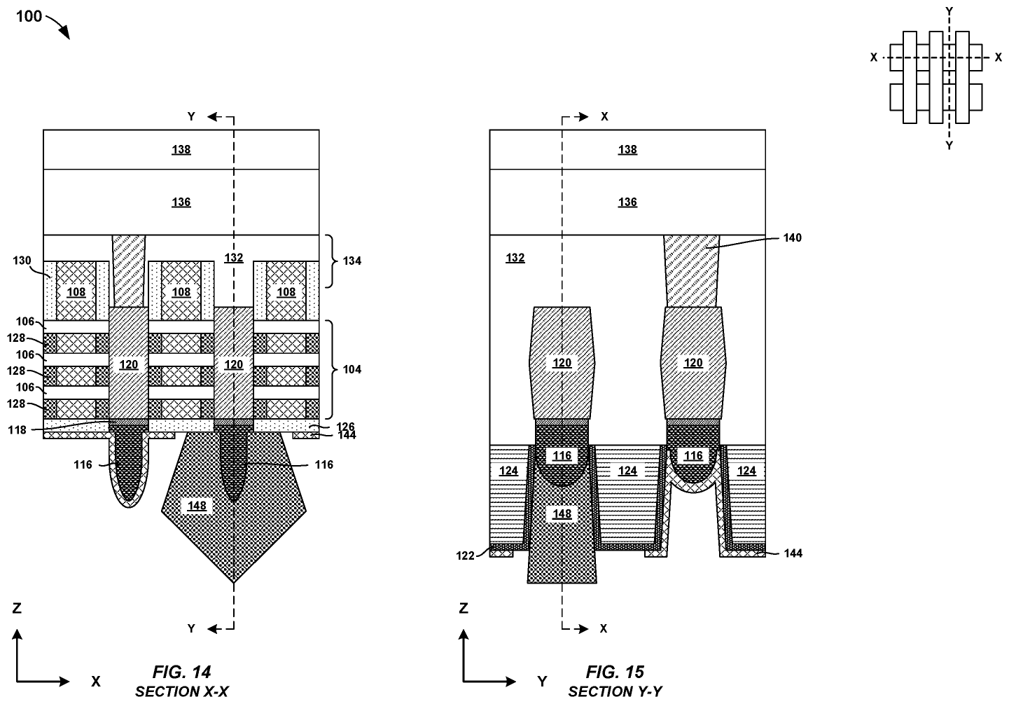

Referring now to FIGS. 14 and 15, the structure 100 is shown after removing the mask 146 and enlarging the exposed placeholders 116 according to an embodiment of the invention. FIG. 14 depicts a cross-sectional view of the structure 100 shown in FIG. 15 taken along line X-X and FIG. 15 depicts a cross-sectional view of the structure 100 shown in FIG. 14 taken along line Y-Y.

First, the mask 146 is removed according to known techniques. Next, the exposed placeholders 116 are enlarged by forming placeholder extensions 148. The placeholder extensions 148 can be formed by epitaxially growing additional sacrificial material from the exposed surfaced of the trimmed placeholder 116. Remember, trimming or erosion of the placeholders 116 is a byproduct, or an unintended consequence, resulting from the selective removal of the top semiconductor layer 114, as previously described above. For example, in an embodiment, the additional sacrificial material is silicon germanium epitaxially grown from the exposed surfaces of the trimmed placeholders 116. In another embodiment, the additional sacrificial material preferably matches the material from which the placeholder 116 was originally formed. In other embodiments, the additional sacrificial material and the placeholders 116 are both made from materials which can be selectively removed together. In all cases, the additional sacrificial material will effectively enlarge the exposed placeholders 116, as illustrated and depicted as the placeholder extensions 148. More specifically, the additional sacrificial material will have a faceted profile consistent with epitaxially growth techniques.

Meanwhile, the dielectric liner 144 protects other surrounding surfaces of the structure 100 from the additional sacrificial material. Said differently, a specific goal of the embodiments disclosed herein is that the additional sacrificial material of the placeholder extensions 148 effectively enlarges only those placeholders 116 located in contact regions—or areas of the structure designed for a backside contacts. In most cases, the placeholder extensions 148 do not contact the dielectric liner 144; however, contact between the placeholder extensions 148 and the dielectric liner 144 is permitted. The dielectric liner 144 also prevents any unwanted merging between adjacent placeholders 116.

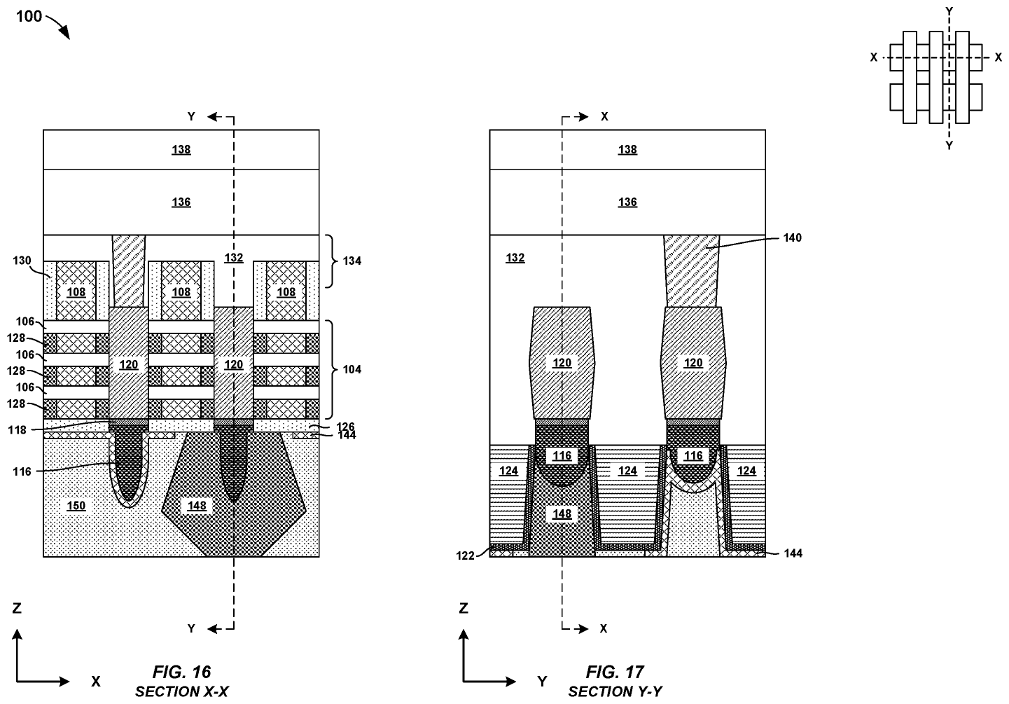

Referring now to FIGS. 16 and 17, the structure 100 is shown after forming a backside dielectric layer 150 according to an embodiment of the invention. FIG. 16 depicts a cross-sectional view of the structure 100 shown in FIG. 17 taken along line X-X and FIG. 17 depicts a cross-sectional view of the structure 100 shown in FIG. 16 taken along line Y-Y.

The backside dielectric layer 150 is deposited according to known techniques. Specifically, a backside dielectric material is blanket deposited across the structure 100. The backside dielectric layer 150 completely covers remaining portions of the dielectric liner 144 and the placeholder extensions 148. After deposition, known chemical mechanical polishing may be used to remove excess portions of the backside dielectric material from bottom surfaces of the structure 100. Critical to the disclosed embodiments, chemical mechanical polishing must continue until the placeholder extensions 148 are exposed, as illustrated. Doing so is necessary for subsequent processing according to embodiment of the present invention.

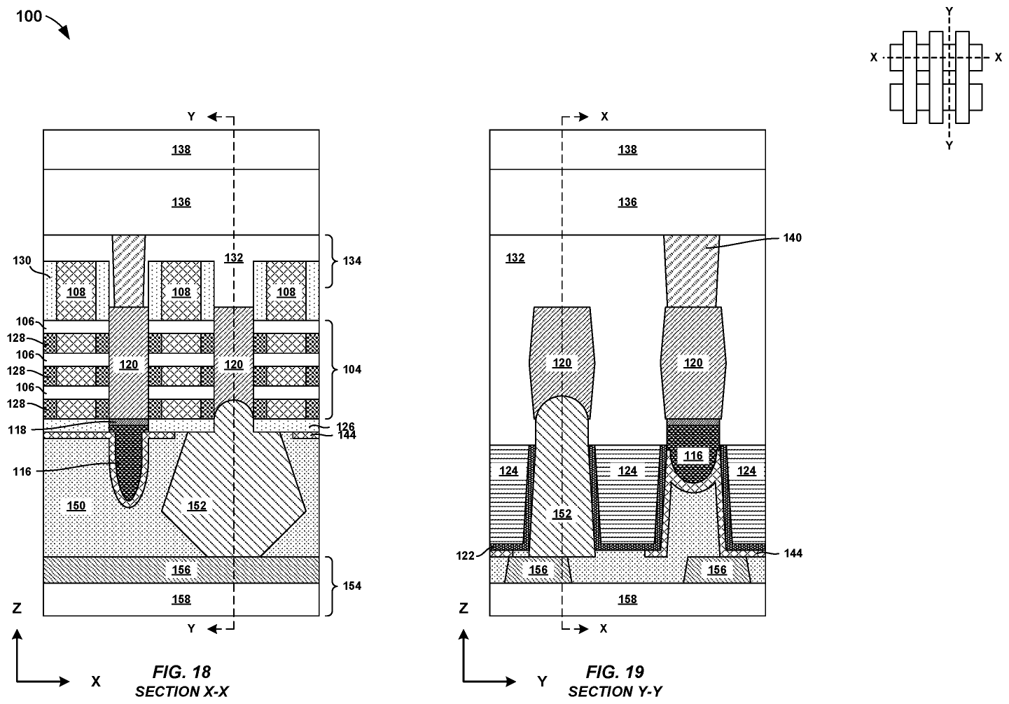

Referring now to FIGS. 18 and 19, the structure 100 is shown after forming removing the placeholders 116 and the placeholder extensions 148, forming a backside contact structures 152, and forming backside wiring layers 154 according to an embodiment of the invention. FIG. 18 depicts a cross-sectional view of the structure 100 shown in FIG. 19 taken along line X-X and FIG. 19 depicts a cross-sectional view of the structure 100 shown in FIG. 18 taken along line Y-Y.

The placeholder extensions 148 exposed by polishing are selectively removed according to known techniques. Specifically, placeholder extensions 148 and placeholders 116 are etched or removed selective to the backside dielectric layer 150, the stack spacers 126, the STI regions, and the buffer layer 118. The placeholder extensions 148 and the placeholders 116 can be removed using compatible selective dry etching techniques.

In doing so, backside contact trenches (not shown) are formed directly beneath the source drain regions 120 without exposing the source drain regions 120 due to the existence of the buffer layer 118. Finally, exposed buffer layers 118 are subsequently removed selective to the surrounding structures according to known techniques. In some cases, gouging of the source drain regions 120 may occur.

Next, the backside contact trenches are filled with a conductive material to form the backside contact structures 152 according to known techniques. The backside contact structures 152 may include any suitable conductive material, such as, for example, copper, ruthenium, aluminum, tungsten, cobalt, or alloys thereof. In some embodiments, a metal silicide is formed at the bottom of the backside contact trenches prior to filling them with the conductive material.

After, excess conductive material can be polished using known techniques until bottommost surfaces of the backside contact structures 152 are flush, or substantially flush, with bottommost surfaces of the backside dielectric layer 150, as illustrated. After polishing, a bottommost surfaces of the backside contact structures 152 are substantially flat. It is noted, the backside contact structures 152 may include, for example, backside source drain contacts, as illustrated, as well as backside gate contacts (not shown). In all cases, a topmost surface of the backside contact structures 152 is above a topmost surface of the placeholders 116, as illustrated. Further, the backside contact structures 152 will have a faceted profile consistent with that of the placeholder extensions 148 described above.

After forming the backside contact structures 152, the backside wiring layers 154 are subsequently formed according to known techniques. The backside wiring layers 154 typically include at least backside power rails 156 and a backside power delivery network 158.

With continued reference to FIGS. 18 and 19, and according to an embodiment, the structure 100 includes a backside contact structure (e.g. 152), where the backside contact structure (e.g. 152) has a faceted profile extending beneath one or more gates (e.g. 108), a placeholder (e.g. 116) adjacent to the backside contact structure (e.g. 152) and directly beneath a source drain region (e.g. 120), and a dielectric liner (e.g. 144) surrounding a bottom portion of the placeholder (e.g. 116).

With continued reference to FIGS. 18 and 19, and according to an embodiment, the structure further includes a buffer layer (e.g. 118) between and physically separating the placeholder (e.g. 116) from the source drain region (e.g. 120).

With continued reference to FIGS. 18 and 19, and according to an embodiment, the structure further includes stack spacers (e.g. 126) between and physically separating the backside contact structure (e.g. 152) from the one or more gates (e.g. 108).

With continued reference to FIGS. 18 and 19, and according to an embodiment, the structure further includes a bottommost surface of the backside contact structure (e.g. 152) is substantially flat and directly contacts a backside power rail (e.g. 156).

With continued reference to FIGS. 18 and 19, and according to an embodiment, the structure further includes the backside contact structure (e.g. 152) is self-aligned to adjacent shallow trench isolation regions (e.g. 122/124).

With continued reference to FIGS. 18 and 19, and according to an embodiment, the structure further includes the dielectric liner (e.g. 144) further disposed along sidewalls and bottoms of shallow trench isolation regions (e.g. 122/124).

With continued reference to FIGS. 18 and 19, and according to an embodiment, the structure further includes a topmost surface of the backside contact structure (e.g. 152) is above a topmost surface of the placeholder (e.g. 116).

With continued reference to FIGS. 18 and 19, and according to an embodiment, the structure 100 includes a backside contact structure (e.g. 152) having a faceted profile extending laterally in a direction perpendicular to one or more gates (e.g. 108), a placeholder (e.g. 116) adjacent to the backside contact structure (e.g. 152) and directly beneath a source drain region (e.g. 120), and a dielectric liner (e.g. 144) surrounding a bottom portion of the placeholder (e.g. 116).

With continued reference to FIGS. 18 and 19, and according to an embodiment, the structure 100 includes a backside contact structure (e.g. 152) directly beneath and contacting a first source drain region, where the backside contact structure (e.g. 152) comprises a faceted profile, a placeholder (e.g. 116) adjacent to the backside contact structure (e.g. 152) and directly beneath a second source drain region (e.g. 120), and a dielectric liner (e.g. 144) surrounding a bottom portion of the placeholder (e.g. 116).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a backside contact structure, wherein the backside contact structure comprises a faceted profile extending beneath one or more gates;
a placeholder adjacent to the backside contact structure and directly beneath a source drain region; and
a dielectric liner surrounding a bottom portion of the placeholder.

2. The semiconductor structure according to claim 1, further comprising:
a buffer layer between and physically separating the placeholder from the source drain region.

3. The semiconductor structure according to claim 1, further comprising:
stack spacers between and physically separating the backside contact structure from the one or more gates.

4. The semiconductor structure according to claim 1, wherein a bottommost surface of the backside contact structure is substantially flat and directly contacts a backside power rail.

5. The semiconductor structure according to claim 1, wherein the backside contact structure is self-aligned to adjacent shallow trench isolation regions.

6. The semiconductor structure according to claim 1, wherein the dielectric liner further disposed along sidewalls and bottoms of shallow trench isolation regions.

7. The semiconductor structure according to claim 1, wherein a topmost surface of the backside contact structure is above a topmost surface of the placeholder.

8. A nanosheet semiconductor structure comprising:
a backside contact structure having a faceted profile extending laterally in a direction perpendicular to one or more gates;
a placeholder adjacent to the backside contact structure and directly beneath a source drain region; and
a dielectric liner surrounding a bottom portion of the placeholder.

9. The semiconductor structure according to claim 8, further comprising:
a buffer layer between and physically separating the placeholder from the source drain region.

10. The semiconductor structure according to claim 8, further comprising:
stack spacers between and physically separating the backside contact structure from the one or more gates.

11. The semiconductor structure according to claim 8, wherein a bottommost surface of the backside contact structure is substantially flat and directly contacts a backside power rail.

12. The semiconductor structure according to claim 8, wherein the backside contact structure is self-aligned to adjacent shallow trench isolation regions.

13. The semiconductor structure according to claim 8, wherein the dielectric liner further disposed along sidewalls and bottoms of shallow trench isolation regions.

14. The semiconductor structure according to claim 8, wherein a topmost surface of the backside contact structure is above a topmost surface of the placeholder.

15. A nanosheet semiconductor structure comprising:
a backside contact structure directly beneath and contacting a first source drain region, wherein the backside contact structure comprises a faceted profile;
a placeholder adjacent to the backside contact structure and directly beneath a second source drain region; and
a dielectric liner surrounding a bottom portion of the placeholder.

16. The semiconductor structure according to claim 15, further comprising:
a buffer layer between and physically separating the placeholder from the source drain region.

17. The semiconductor structure according to claim 15, further comprising:
stack spacers between and physically separating the backside contact structure from the one or more gates.

18. The semiconductor structure according to claim 15, wherein a bottommost surface of the backside contact structure is substantially flat and directly contacts a backside power rail.

19. The semiconductor structure according to claim 15, wherein the backside contact structure is self-aligned to adjacent shallow trench isolation regions.

20. The semiconductor structure according to claim 15, wherein the dielectric liner further disposed along sidewalls and bottoms of shallow trench isolation regions.
